(19) United States
(12) Patent Application Publication
(10) Pub. No.: US 2015/0318268 A1
(43) Pub. Date: Nov. 5, 2015

(54) MULTI-CHIP PACKAGE AND METHOD OF MANUFACTURING THE SAME

(71) Applicant: SAMSUNG ELECTRONICS CO., LTD., SUWON-SI (KR)

(72) Inventors: JUNG-SEOK AHN, SEOUL (KR); SANG-WON KIM, SEOUL (KR); YOUNG-SANG CHO, YONGIN-SI (KR); KWANG-CHUL CHOI, Hwaseong-si (KR); SUNG-EUN PYO, YONGIN-SI (KR)

(21) Appl. No.: 14/697,210

(22) Filed: Apr. 27, 2015

Related U.S. Application Data
(62) Division of application No. 13/653,727, filed on Oct. 17, 2012.

(30) Foreign Application Priority Data
Jan. 18, 2012 (KR) 10-2012-0005822

(51) Int. Cl. H01L 25/065; H01L 23/31; H01L 23/522; H01L 23/528; H01L 23/00

(52) U.S. Cl. CPC H01L 25/0657; H01L 23/528; H01L 24/17; H01L 23/5226; H01L 23/3157; H01L 2225/06513; H01L 2224/16148; H01L 2224/13025; H01L 2225/06541

(57) ABSTRACT

A multi-chip package includes a first semiconductor chip and a second semiconductor chip. The first semiconductor chip has a first active surface. The second semiconductor chip has a second active surface facing the first active surface. The second active surface is electrically connected with the first active surface and the first active surface of the first semiconductor chip and the second active surface of the second semiconductor chip are bonded to each other without an adhesive.

### CROSS-RELATED APPLICATION

This application is a Division of U.S. patent application Ser. No. 13/653,727, filed Oct. 17, 2012, which claims priority under 35 USC §119 to Korean Patent Application No. 10-2012-0005822, filed on Jan. 18, 2012, the disclosure of which is hereby incorporated by reference herein in its entirety.

### BACKGROUND

1. Technical Field

Example embodiments relate to a multi-chip package and a method of manufacturing the same. More particularly, example embodiments relate to a multi-chip package including a plurality of stacked semiconductor chips, and a method of manufacturing the multi-chip package.

2. Description of the Related Art

Generally, a plurality of semiconductor fabrication processes may be performed on a semiconductor substrate to form a plurality of semiconductor chips. To mount the semiconductor chips on a printed circuit board (PCB), a packaging process may be performed on the semiconductor chips to form semiconductor packages.

To increase a storage capacity of the semiconductor package, a multi-chip package including a plurality of the semiconductor chips sequentially stacked may be widely developed. The multi-chip package may be manufactured by, for example, stacking the semiconductor chips that may be formed by cutting a wafer, or by bonding wafers and cutting the bonded wafers.

In related arts of wafer bonding, a bonding time may be too long because an adhesive may be coated on the wafers and the wafers may then be bonded at a high temperature. Further, the adhesive may remain on stack bumps between the wafers. The remaining adhesive may cause electrical disconnections between the stack bumps. Furthermore, the related arts may necessarily require a process for supporting the wafers, and a process for molding the wafers, so that these wafer bonding processes may be complicated processes.

### SUMMARY

Example embodiments provide a multi-chip package having increased electrical connection reliability.

Example embodiments also provide a method of manufacturing the above-mentioned multi-chip package.

According to an example embodiment , there is provided a multi-chip package. The multi-chip package includes a first semiconductor chip and a second semiconductor chip. The first semiconductor chip has a first active surface. The second semiconductor chip has a second active surface facing the first active surface. The second active surface is electrically connected with the first active surface and the first active surface of the first semiconductor chip and the second active surface of the second semiconductor chip are bonded to each other without an adhesive.

In example embodiments, the first semiconductor chip may include a first bonding pad disposed on the first active surface, and a first plug extending from the first bonding pad through the first semiconductor chip.

In example embodiments, the second semiconductor chip may include a second bonding pad disposed on the second active surface. The second semiconductor chip may further include a second plug electrically connected to the second bonding pad.

In example embodiments, the multi-chip package may further include a first stack bump formed on the first active surface, and a second stack bump formed on the second active surface to electrically make contact with the first stack bump.

In example embodiments, the multi-chip package may further include a mount bump mounted on the first plug.

In example embodiments, the multi-chip package may further include an underfilling layer formed between the first active surface and the second active surface.

According to some example embodiment, there is provided a method of manufacturing a multi-chip package. In the method of manufacturing the multi-chip package, a first active surface of a first wafer having a first plug iselectrically connected with a second active surface of a second wafer. Also, the first active surface of the first wafer and the second active surface of the second wafer face each other and are bonded to each other without an adhesive. The first wafer and the second wafer are cut to form a plurality of the multi-chip packages.

In example embodiments, the electrically connecting the first active surface with the second active surface may include forming a first stack bump on the first active surface, forming a second stack bump on the second active surface, and bonding the first stack bump and the second stack bump to each other.

In example embodiments, the method may further include forming a passageway in fluidic communication with a space between the first active surface and the second active surface, and injecting an underfilling material into the space between the first active surface and the second surface through the passageway to form an underfilling layer in the space between the first active surface and the second active surface.

In example embodiments, the method may further include covering the first active surface with an underfilling layer.

In example embodiments, the method may further include forming mount bump on the first plug.

In example embodiments, forming the mount bump may include partially removing the first wafer to expose the first plug, and forming the mount bump on the exposed first plug.

In example embodiments, the method may further include forming a second plug through the second wafer. The second plug may be electrically connected with the second active surface.

In accordance with an example embodiment, a method of manufacturing a multi-chip package is provided. The method includes providing a first wafer having a first bonding pad disposed on a first active surface of the first wafer and a first plug extending downwardly from the first bonding pad, forming a first stack bump on the first bonding pad, providing a second wafer having a second bonding pad disposed on a second active surface of second wafer, forming a second stack bump on the second bonding pad, cutting from an upper surface of the second wafer to a lower surface of the second wafer to thereby form a passageway in the second wafer, wherein the passageway is not exposed through the lower surface of the second wafer, stacking the first wafer on the second wafer such that the first stack bump makes contact with the second stack bump and wherein the first active surface of the first wafer faces the second active surface of the second wafer, applying heat to the first stack bump and the second stack bump to thereby attach the first stack bump and the second stack bump to each other and electrically connect the first wafer and the second wafer to each other, reversing the first and second wafers such that the second wafer is positioned over the first wafer and removing a portion of the upper surface of the second wafer until the passageway is exposed, reversing the first and second wafers such that the first wafer is positioned over the second wafer and removing a portion of an upper surface of the first wafer until the first plug is exposed.

In addition, the method further includes forming a pad on the exposed portion of the first plug, forming a mounting bump on the pad, reversing the first and second wafers such that second first wafer is positioned over the first wafer having the pad and the mounting bump formed thereon, attaching a supporting tape to a lower surface of the first wafer, removing a portion of the upper surface of the second wafer with the first and second wafers supported by the supporting tape to thereby reduce a thickness of the second wafer, attaching a cutting tape to the lower surface of the second wafer having the reduced thickness and cutting the first and second wafers along scribe lines of the first and second wafers.

According to example embodiments, the first active surface of the first wafer may be bonded to the second active surface of the second wafer with the first active surface and the second active surface facing each other. Thus, it may not be necessary to use an adhesive, which may cause electrical disconnections between the first wafer and the second wafer, for bonding the first wafer and the second wafer to each other. As a result, the multi-chip package may have increased electrical connection reliability. Further, the method may not include a process for supporting the wafers, and a process for molding the wafers, so that the multi-chip package may be manufactured by relatively simple processes in a relatively short period of time.

### BRIEF DESCRIPTION OF THE DRAWINGS

Example embodiments can be more clearly understood from the following detailed description taken in conjunction with the accompanying drawings. FIGS. 1 to 24 represent non-limiting, example embodiments as described herein.

FIG. 1 is a cross-sectional view illustrating a multi-chip package in accordance with an example embodiment;

FIGS. 2 to 13 are cross-sectional views illustrating the multi-chip package in FIG. 1;

FIGS. 14 to 23 are cross-sectional views illustrating the multi-chip package in FIG. 1 in accordance with an example embodiment; and

FIG. 24 is a cross-sectional view illustrating a multi-chip package in accordance with an example embodiment.

### DETAILED DESCRIPTION OF EXAMPLE EMBODIMENTS

Various example embodiments will be described more fully hereinafter with reference to the accompanying drawings, in which some example embodiments are shown. Example embodiments of the present invention may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. Like numerals refer to like elements throughout. As used herein, the term “and/or” includes any and all combinations of one or more of the associated listed items.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Hereinafter, example embodiments will be explained in detail with reference to the accompanying drawings.

FIG. 1 is a cross-sectional view illustrating a multi-chip package in accordance with an example embodiment.

Referring to FIG. 1, a multi-chip package 100 of this example embodiment may include, for example, a first semiconductor chip 110 and a second semiconductor chip 120. In example embodiments, the second semiconductor chip 120 may be, for example, placed over the first semiconductor chip 110.

In example embodiments, the first semiconductor chip 110 may have a first active surface 112. The first active surface 112 may be oriented toward, for example, an upper direction. That is, the first active surface 112 may correspond to an upper surface of the first semiconductor chip 110. The first semiconductor chip 110 may have, for example, first bonding pads 114 and first plugs 116. The first bonding pads 114 may be arranged on the first active surface 112 of the first semiconductor chip 110. That is, the first bonding pads 114 may be, for example, oriented toward the upward direction.

In example embodiments, the first plugs 116 may be, for example, vertically built in the first semiconductor chip 110. Each of the first plugs 116 may have an upper end and a lower end. The upper end of the first plug 116 may make contact with, for example, the first bonding pad 114. Thus, the upper end of the first plug 116 may be electrically connected to the first bonding pad 114. The lower end of the first plug 116 may, for example, be exposed through a lower surface of the first semiconductor chip 110.

In example embodiments, the second semiconductor chip 120 may have a second active surface 122. The second active surface 122 may be oriented toward, for example, a downward direction. That is, the second active surface 122 may correspond to a lower surface of the second semiconductor chip 120. Thus, the second active surface 122 of the second semiconductor chip 120 may face the first active surface 112 of the first semiconductor chip 110.

In example embodiments, the second semiconductor chip 120 may have, for example, second bonding pads 124. The second bonding pads 124 may be arranged on the second active surface 122 of the second semiconductor chip 120. That is, the second bonding pads 124 may be, for example, oriented toward the downward direction. Therefore, the second bonding pads 124 may face the first bonding pads 114.

First stack bumps 130 may be formed on the first bonding pads 114. Second stack bumps 132 may be formed on the second bonding pads 124. Thus, the first stack bumps 130 may face the second stack bumps 132. The first stack bumps 130 and the second stack bumps 132 may be bonded to each other, so that the first semiconductor chip 110 and the second semiconductor chip 120 may be electrically connected with each other via the first stack bumps 130 and the second stack bumps 132.

A space between the first active surface 112 and the second active surface 122 may be filled with, for example, an underfilling layer 140. In example embodiments, the underfilling layer 140 may include an epoxy molding compound (EMC).

Pads 118 may be formed on, for example, the lower ends of the first plugs 116. Mount bumps 134 may be formed on the pads 118. The mount bumps 134 may be mounted on a package substrate (not shown).

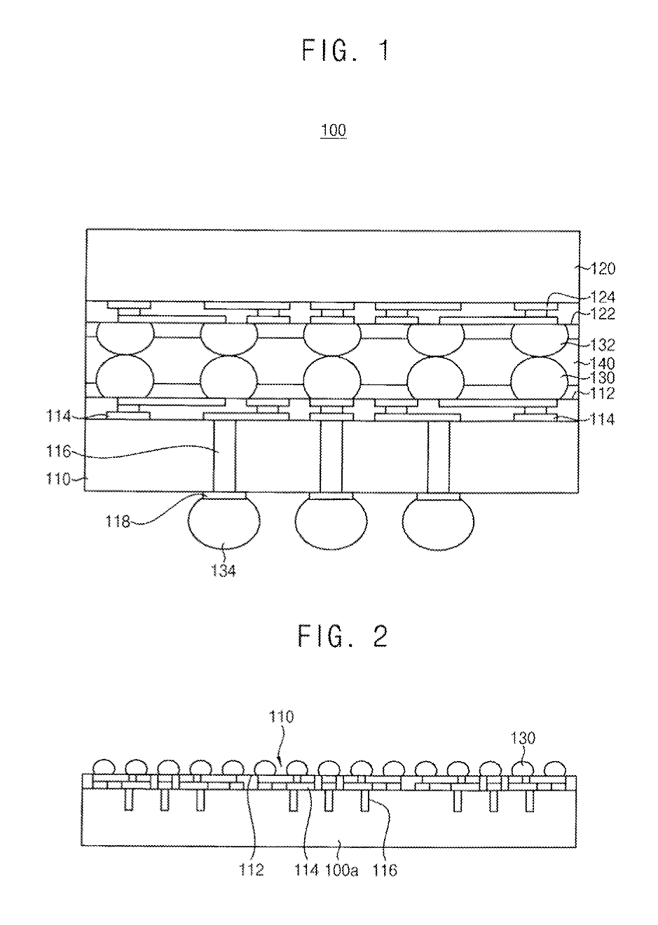

FIGS. 2 to 13 are cross-sectional views illustrating the multi-chip package in FIG. 1.

Referring to FIG. 2, a first wafer 100a may be prepared. In example embodiments, the first wafer 100a may include a plurality of the first semiconductor chips 110. Each of the first semiconductor chips 110 may include, for example, the first bonding pads 114 and the first plugs 116. The first bonding pads 114 may be arranged on the first active surface 112 of the first semiconductor chip 110. The first active surface 112 may be oriented toward, for example, the upward direction. The first plugs 116 may be, for example, downwardly extended from the first bonding pads 114. The first plugs 116 may, for example, not be exposed through the lower surface of the first semiconductor chip 110.

The first stack bumps 130 may be formed on the first bonding pads 114. In example embodiments, because the first bonding pads 114 may be arranged on the first active surface 112, the first stack bumps 130 may also be arranged on the first active surface 112. The first stack bumps 130 may include, for example, solder bumps.

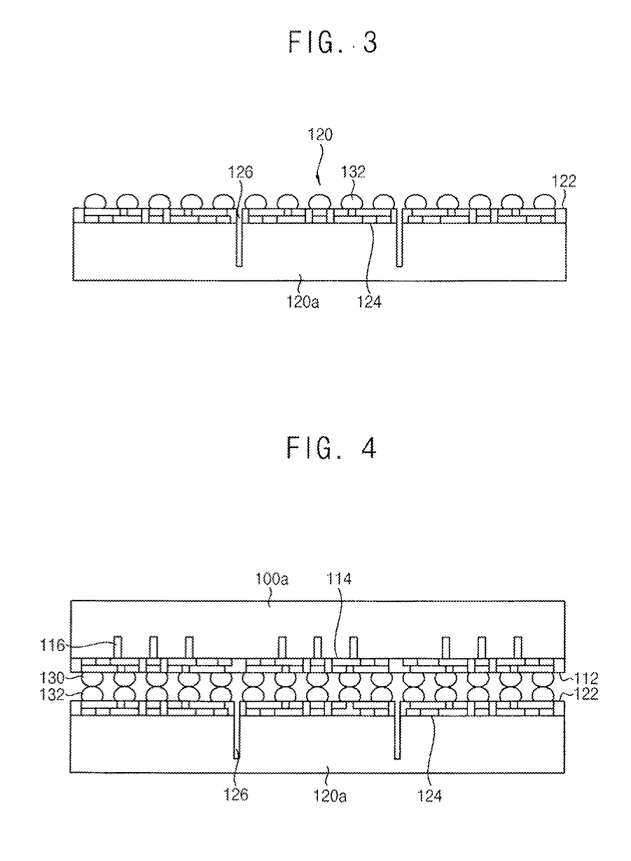

Referring to FIG. 3, a second wafer 120a may be prepared. In example embodiments, the second wafer 120a may include a plurality of the second semiconductor chips 120. Each of the second semiconductor chips 120 may include, for example, the second bonding pads 124. The second bonding pads 124 may be arranged on the second active surface 122 of the second semiconductor chip 120. The second active surface 122 may be, for example, oriented toward the upward direction. The second stack bumps 132 may be formed on the second bonding pads 124. The second stack bumps 132 may include, for example, solder bumps.

For example, scribe lanes of the second wafer 120a may be partially cut from the upper surface toward a lower surface of the second wafer 120a to form a passageway 126. In example embodiments, the passageway 126 may, for example, not be exposed through the lower surface of the second wafer 120a.

Referring to FIG. 4, the first wafer 110a may be stacked on the second wafer 120a. In example embodiments, the first stack bumps 130 may make contact with the second stack bumps 132, respectively. That is, the first active surface 112 of the first semiconductor chip 110 may face the second active surface 122 of the second semiconductor chip 120.

For example, heat may be applied to the first stack bumps 130 and the second stack bumps 132 to firmly attach the first stack bumps 130 and the second stack bumps 132 to each other. Thus, the first wafer 110a and the second wafer 120a may be electrically connected with each other and the first stack bumps 130 and the second stack bumps 132 may be firmly attached to each other.

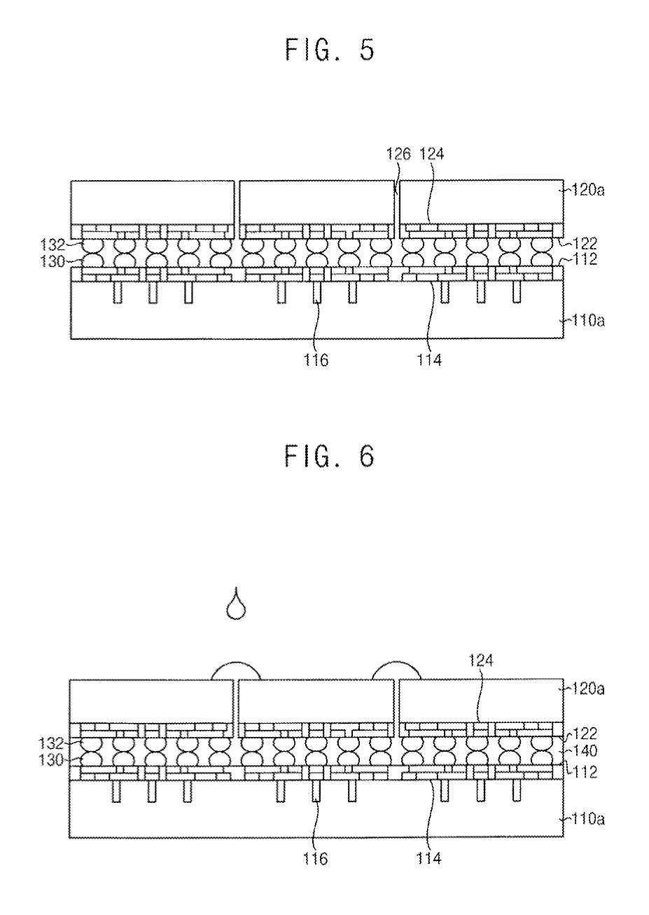

For example, referring to FIG. 5, the attached first and second wafers 110a and 120a may be reversed. Thus, the second wafer 120a may be positioned over the first wafer 110a.

The upper surface of the second wafer 120a may, for example, be removed until the passageway 126 may be exposed. In example embodiments, the upper surface of the second wafer 120a may be removed by, for example, an etching process, a grinding process, etc.

For example, referring to FIG. 6, an underfilling material may be injected through the passageway 126. The space between the first active surface 112 and the second active surface 122 may be filled with the underfilling material. The underfilling material may, for example, be annealed to form the underfilling layer 140 between the first active surface 112 and the second active surface 122. In example embodiments, the underfilling layer 140 may have, for example, a protrusion protruded from the upper surface of the second wafer 120a.

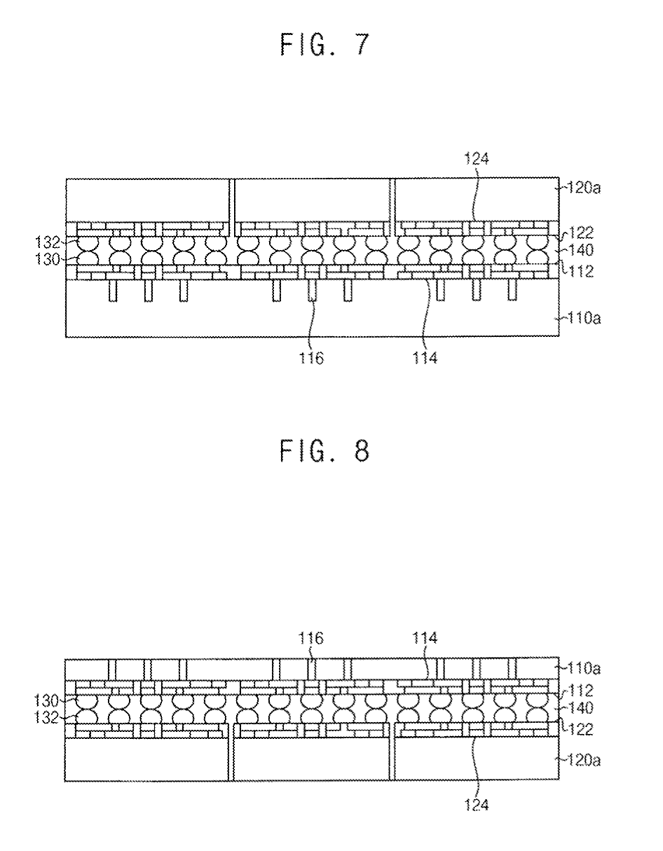

Referring to FIG. 7, the upper surface of the second wafer 120a may, for example, be partially removed to remove the protrusion of the underfilling layer 140. In example embodiments, the protrusion of the underfilling layer 140 may be removed by, for example, a grinding process. Alternatively, for example, when the underfilling layer 140 may not have the protrusion, the process for removing the upper surface of the second wafer 120a may be omitted.

Referring to FIG. 8, the first wafer 110a and the second wafer 120a may, for example, be reversed. Thus, the first wafer 110a may be positioned over the second wafer 120a.

The upper surface of the first wafer 110a may be, for example, removed until the first plugs 116 may be exposed. In example embodiments, the upper surface of the first wafer 110a may be removed by, for example, a grinding process.

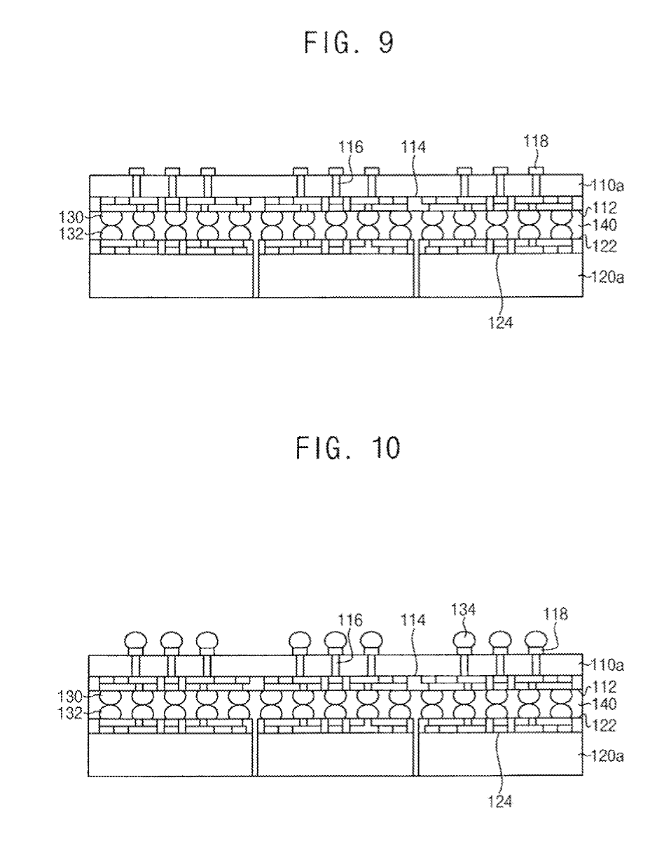

Referring to FIG. 9, the pads 118 may be formed on, for example, the exposed portions of the first plugs 116. In example embodiments, the pads 118 may include, for example, metal.

Referring to FIG. 10, the mount bumps 134 may be formed on the pads 118. In example embodiments, the mount bumps 134 may include, for example, solder bumps.

Referring to FIG. 11, the first wafer 110a and the second wafer 120a may, for example, be reversed. Thus, the second wafer 120a may be positioned over the first wafer 110a.

For example, a supporting tape 150 may be attached to the lower surface of the first wafer 110a. The upper surface of the second wafer 120a may, for example, be partially removed with the first and second wafers 110a and 120a supported by the supporting tape 150 to reduce the thickness of the second wafer 120a.

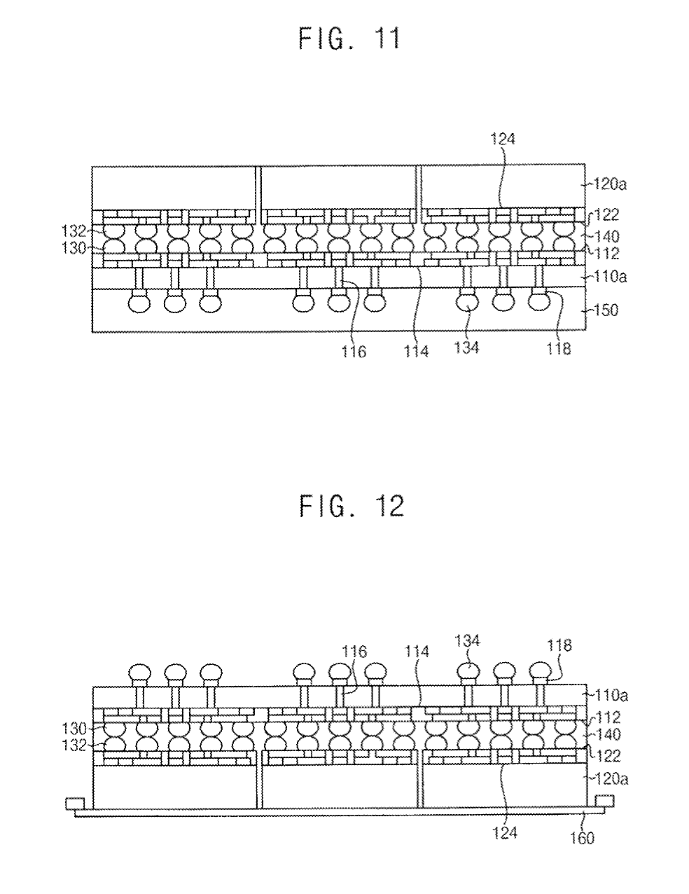

Referring to FIG. 12, the first wafer 110a and the second wafer 120a may, for example, be reversed. Thus, the first wafer 110a may be positioned over the second wafer 120a. For example, a cutting tape 160 may be attached to the lower surface of the second wafer 120a.

As can be see in FIG. 12, the supporting tape 150 has been removed. In an embodiment, the supporting tape 150 can be removed, for example, prior to attaching the cutting tape 160 to the lower surface of the second wafer 120a. Alternatively, for example, in an embodiment, the supporting tape 150 can be removed after attaching the cutting tape 160 to the lower surface of the second wafer 120a.

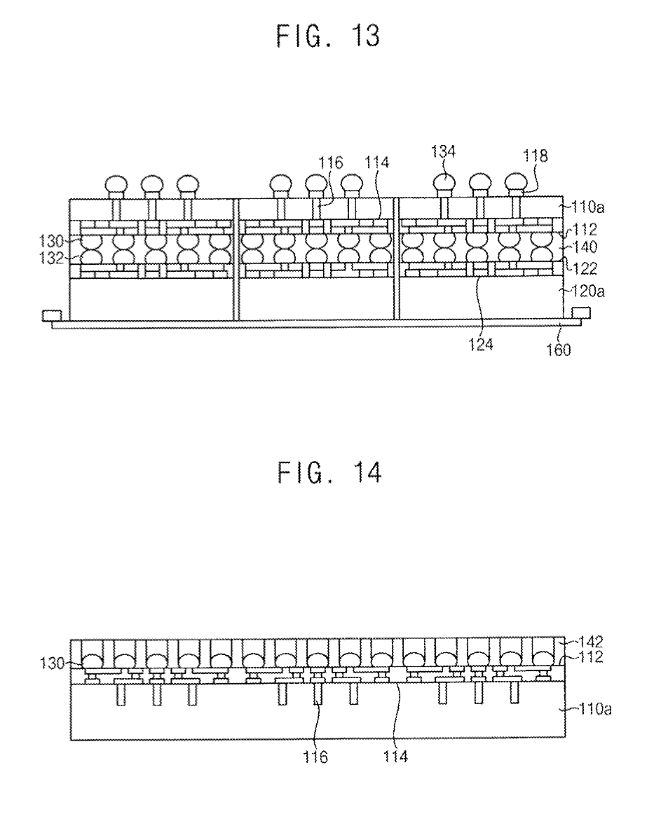

Referring to FIG. 13, the first wafer 110a and the second wafer 120a may, for example, be cut along the scribe lanes. The cutting tape 160 may be removed to complete the multi-chip package 100 in FIG. 1.

According to this example embodiment, the first active surface 112 of the first wafer 110a may be bonded to the second active surface 122 of the second wafer 120a with the first active surface 112 and the second active surface 122 facing each other. Thus, it may not be necessary to use an adhesive, which may cause electrical disconnections between the first wafer 110a and the second wafer 120a, for bonding the first wafer 110a and the second wafer 120a to each other. As a result, the multi-chip package 100 may have increased electrical connection reliability. Further, the method may not include a process for supporting the wafers, and a process for molding the wafers, so that the multi-chip package may be manufactured by relatively simple processes in a relatively short period of time.

FIGS. 14 to 23 are cross-sectional views illustrating the multi-chip package in FIG. 1 in accordance with an example embodiment.

Referring to FIG. 14, a first wafer 110a may be prepared. In example embodiments, the first wafer 110a may include a plurality of the first semiconductor chips 110. Each of the first semiconductor chips 110 may include, for example, the first bonding pads 114 and the first plugs 116. The first bonding pads 114 may be arranged on the first active surface 112 of the first semiconductor chip 110. The first active surface 112 may be oriented toward, for example, the upward direction. The first plugs 116 may be, for example, downwardly extended from the first bonding pads 114. The first plugs 116 may, for example, not be exposed through the lower surface of the first semiconductor chip 110.

The first stack bumps 130 may be formed on the first bonding pads 114. In example embodiments, because the first bonding pads 114 may be arranged on the first active surface 112, the first stack bumps 130 may also be arranged on the first active surface 112. The first stack bumps 130 may include, for example, solder bumps.

For example, an underfilling layer 142 may be formed on the upper surface of the first wafer 110a. The underfilling layer 142 may have, for example, openings configured to expose the first stack bumps 130.

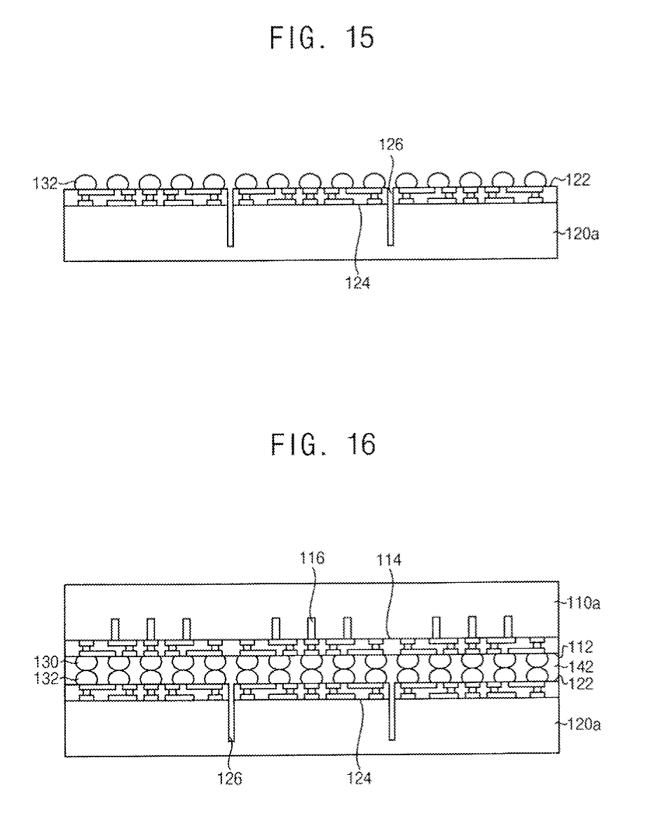

Referring to FIG. 15, a second wafer 120a may be prepared. In example embodiments, the second wafer 120a may include a plurality of the second semiconductor chips 120. Each of the second semiconductor chips 120 may include, for example, the second bonding pads 124. The second bonding pads 124 may be arranged on the second active surface 122 of the second semiconductor chip 120. The second active surface 122 may, for example, be oriented toward the upward direction. The second stack bumps 132 may be formed on the second bonding pads 124. The second stack bumps 132 may include, for example, solder bumps.

For example, scribe lanes of the second wafer 120a may be partially cut from the upper surface toward a lower surface of the second wafer 120a to form a passageway 126. In example embodiments, the passageway 126 may, for example, not be exposed through the lower surface of the second wafer 120a.

Referring to FIG. 16, the first wafer 110a may be stacked on the second wafer 120a. In example embodiments, the first stack bumps 130 may, for example, make contact with the second stack bumps 132, respectively. That is, the first active surface 112 of the first semiconductor chip 110 may face the second active face 122 of the second semiconductor chip 120.

For example, heat may be applied to the first stack bumps 130 and the second stack bumps 132 to firmly attach the first stack bumps 130 and the second stack bumps 132 to each other. Thus, the first wafer 110a and the second wafer 120a may be electrically connected with each other and the first stack bumps 130 and the second stack bumps 132 may be firmly attached to each other.

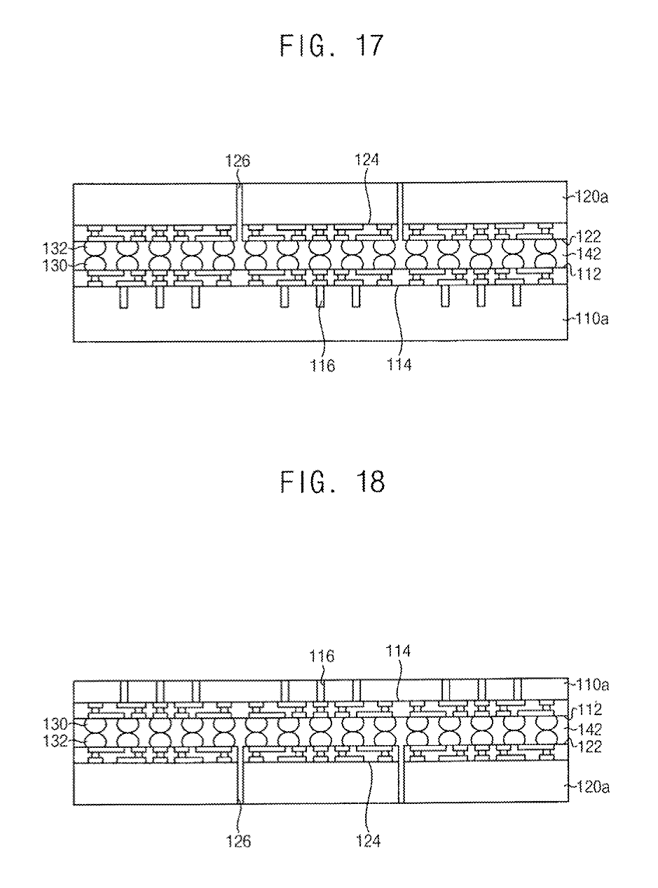

Referring to FIG. 17, the upper surface of the second wafer 120a may, for example, be partially removed to reduce the thickness of the second wafer 120a.

Referring to FIG. 18, the first wafer 110a and the second wafer 120a may, for example, be reversed. Thus, the first wafer 110a may be positioned over the second wafer 120a.

The upper surface of the first wafer 110a may, for example, be removed until the first plugs 116 may be exposed. In example embodiments, the upper surface of the first wafer 110a may be removed by, for example, a grinding process.

For example, referring to FIG. 19, the pads 118 may be formed on the exposed portions of the first plugs 116. In example embodiments, the pads 118 may include, for example, metal.

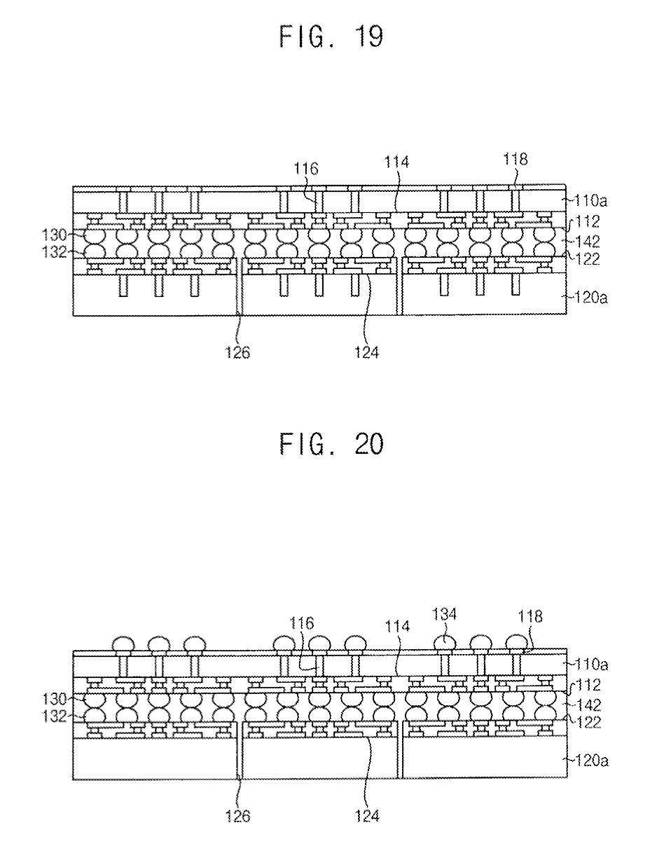

Referring to FIG. 20, the mount bumps 134 may be formed on the pads 118. In example embodiments, the mount bumps 134 may include, for example, solder bumps.

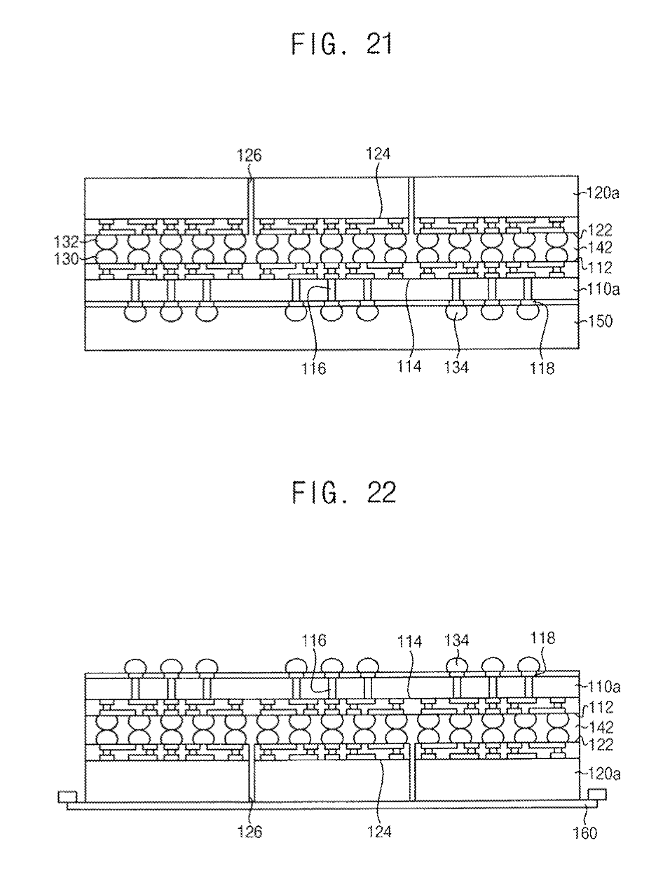

Referring to FIG. 21, the first wafer 110a and the second wafer 120a may, for example, be reversed. Thus, the second wafer 120a may be positioned over the first wafer 110a.

For example, a supporting tape 150 may be attached to the lower surface of the first wafer 110a. The upper surface of the second wafer 120a may, for example, be partially removed with the first and second wafers 110a and 120a supported by the supporting tape 150 to reduce the thickness of the second wafer 120a.

Referring to FIG. 22, the first wafer 110a and the second wafer 120a may, for example, be reversed. Thus, the first wafer 110a may be positioned over the second wafer 120a. For example, a cutting tape 160 may be attached to the lower surface of the second wafer 120a.

As can be see in FIG. 22, the supporting tape 150 has been removed. In an embodiment, the supporting tape 150 can be removed, for example, prior to attaching the cutting tape 160 to the lower surface of the second wafer 120a. Alternatively, for example, in an embodiment, the supporting tape 150 can be removed after attaching the cutting tape 160 to the lower surface of the second wafer 120a.

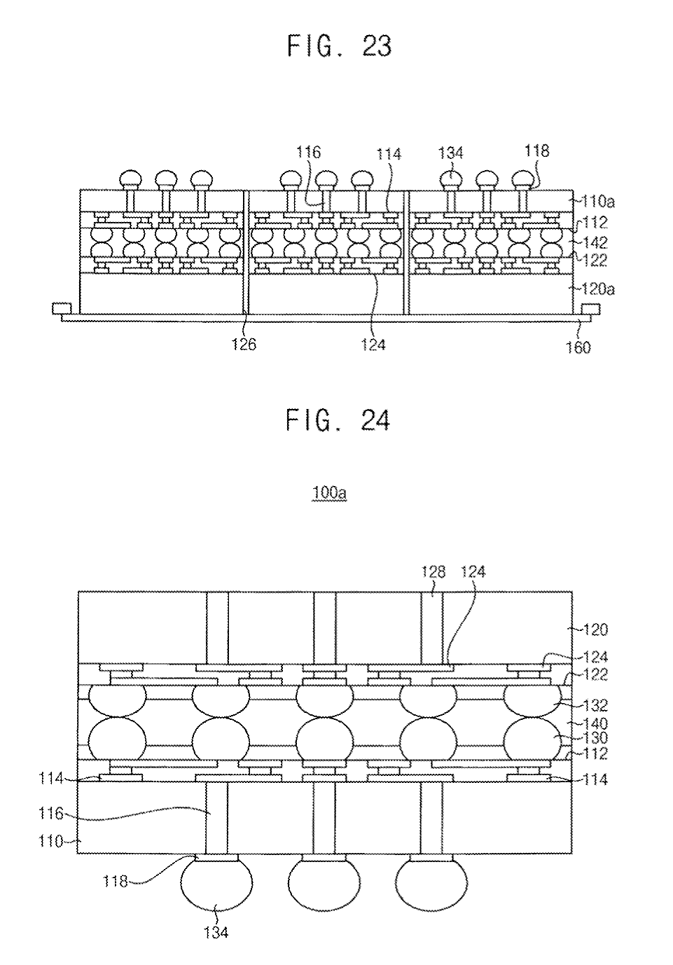

Referring to FIG. 23, the first wafer 110a and the second wafer 120a may, for example, be cut along the scribe lanes. The cutting tape 160 may be removed to complete the multi-chip package 100 in FIG. 1.

According to this example embodiment, the underfilling layer 142 may be previously formed on the first wafer 110a. Thus, a process for forming the underfilling layer between the first active surface 112 and the second active surface 122 after attaching the first wafer 110a and the second wafer 120a to each other may be omitted. As a result, the multi-chip package 100 may be manufactured by relatively more simple processes.

FIG. 24 is a cross-sectional view illustrating a multi-chip package in accordance with example embodiments.

A multi-chip package 100a of this example embodiment may include elements substantially the same as those of the multi-chip package 100 in FIG. 1 except for further including second plugs 128. Thus, the same reference numerals may refer to the same elements and any further illustrations with respect to the same elements may be omitted for brevity.

Referring to FIG. 24, the second semiconductor chip 120 may further include, for example, the second plugs 128. The second plugs 128 may be extended from, for example, the second bonding pads 124. The second plugs 128 may be, for example, exposed through the upper surface of the second semiconductor chip 120.

For example, in example embodiments, stack bumps (not shown) may be formed on the second plugs 128. Thus, an additional semiconductor chip may be stacked on the second semiconductor chip 120. That is, the second plugs 128 may be used for stacking, for example, at least three semiconductor chips.

A method of manufacturing the multi-chip package 100a may include processes substantially the same as those illustrated with reference to FIGS. 2 to 13 or FIGS. 14 to 23 except for further including a process for forming the second plugs 128 in the second semiconductor chip 120. Thus, any further description of the method of manufacturing the multi-chip package 100a may be omitted.

According to example embodiments, the first active surface 112 of the first wafer 110a may be bonded to the second active surface 122 of the second wafer 120a with the first active surface 112 and the second active surface 122 facing each other. Thus, it may not be necessary to use an adhesive, which may cause electrical disconnections between the first wafer 110a and the second wafer 120a, for bonding the first wafer 110a and the second wafer 120a to each other. As a result, the multi-chip package 100, 100a may have increased electrical connection reliability. Further, the method may not include a process for supporting the wafers, and a process for molding the wafers, so that the multi-chip package may be manufactured by relatively simple processes in a relatively short period of time.

Having described example embodiments of the present invention, it is further noted that it is readily apparent to those of ordinary skill in the art that various modifications may be made without departing from the spirit and scope of the invention which is defined by the metes and bounds of the appended claims.

What is claimed is:

1. A multi-chip package comprising:
a first semiconductor chip having a first active surface;
a second semiconductor chip having a second active surface, wherein the second active surface faces the first active surface and is electrically connected with the first active surface, and wherein the first active surface of the first semiconductor chip and the second active surface of the second semiconductor chip are bonded to each other;
a first stack bump disposed on the first active surface;
a second stack bump disposed on the second active surface, and wherein the second stack bump electrically makes contact with the first stack bump; and
an underfilling layer disposed between the first active surface and the second active surface.

2. The multi-chip package of claim 1, wherein the first semiconductor chip comprises:
a first bonding pad disposed on the first active surface; and
a first plug extending from the first bonding pad and disposed through the first semiconductor chip.

3. The multi-chip package of claim 2, further comprising a mount bump mounted on the first plug.

4. The multi-chip package of claim 1, wherein the second semiconductor chip comprises a second bonding pad disposed on the second active surface.

5. The multi-chip package of claim 4, wherein the second semiconductor chip further comprises a second plug electrically connected with the second bonding pad.
